(19) United States
(12) Patent Application Publication
(10) Pub. No.: US 2009/0014881 A1
(43) Pub. Date: Jan. 15, 2009

(54) SEMICONDUCTOR DEVICE, AND METHOD AND APPARATUS FOR MANUFACTURING SAME

(75) Inventors: Kazuhiko Endo, Ibaraki (JP); Naoki Shirakawa, Ibaraki (JP); Eishi Gofuku, Ibaraki (JP); Shinichi Ikeda, Ibaraki (JP); Yoshiyuki Yoshida, Ibaraki (JP)

Correspondence Address: OBLON, SPIVAK, MCCLELLAND MAIER & NEUSTADT, P.C., 1940 DUKE STREET, ALEXANDRIA, VA, 22314, US

(73) Assignee: NATIONAL INST OF ADV INDUSTRIAL SCIENCE AND TECH.

(21) Appl. No.: 11/815,151

(22) PCT Filed: Jan. 27, 2006
(86) PCT No.: PCT/JP2006/301295

§ 371 Date: Feb. 15, 2008

(30) Foreign Application Priority Data
Feb. 2, 2005 (JP) 2005-026400

(51) Int. Cl. H01L 23/52; H01L 21/4763; C23C 16/00

(52) U.S. Cl. 257/758; 438/622; 118/724; 257/E23.141; 257/E21.495

(57) ABSTRACT

For the purpose of removing an oxide film on the surface of a varying metal electroconductive material used for wiring in a semiconductor device without inflicting damage on a peripheral structure, the oxide film formed on the surface of a metal electroconductive region 12 is subjected to a reducing treatment that is effected by placing the metal electroconductive region 12 in a reducing treatment chamber 22, causing an oxygen pump 30 to introduce into the reducing treatment chamber 22 an inert gas having at least an oxygen partial pressure thereof suppressed to 1×10⁻¹³ atmosphere or less and heating the metal electroconductive region 12 with a heating device 25.

### TECHNICAL FIELD

This invention relates to a semiconductor device containing a metal (inclusive of alloy) electroconductive region including a metal electric wiring and the like, and a method and apparatus for the fabrication thereof and particularly relates to the improvement in and relating to effective removal of an oxide film on the surface of the metal electroconductive region susceptible to oxidation during the course of fabrication.

### BACKGROUND ART

In recent years, the trend of LSI (large scale integration) toward higher operating speed and greater degree of integration has been urging contraction of the device rule. Various novel materials have been being introduced in succession with a view to cutting to the fullest possible extent the parasitic resistance and the parasitic capacitance tending to grow in consequence of this contraction and consequently enabling formation of an ever finer configuration. Even for geometrically configured contrivances, such as multilayer interwirings, numerous proposals worthy of general recognition have been made. Concerning the greatest problem attendant on the contraction, namely the fact that the wiring resistance and the interwiring capacity increase in inverse proportion to the contraction of the wiring size and the wiring interval, it cannot be justly said that the measure for radical improvement has been perfected. In fact, the growth of the wiring resistance and the interwiring capacity has been entailing such problems as substantially increasing the delay constant of a circuit and inhibiting the high-speed operation of a device.

Nevertheless, as conventional measures, such contrivances as using copper (Cu) of lowest possible resistance or an alloy thereof as metal electroconductive region material in the place of Al that has been heretofore a principal material or an alloy thereof and using insulating films of low permittivity, such as organic insulating films like SiOF film and SiOC film having lower permittivities than the classical SiO₂ film (having a relative permittivity of about 4.2) or SiC film and SiCN film having lower permittivities than the SiN film (having a relative permittivity of 7) around the electric wiring in a semiconductor device or in an embedded layer in the periphery of each device have found general recognition. As concerns electroconductive materials, besides using the Cu, the introduction of various metals, such as Ni, Co, Ta and Ti, to the LSI transistor devices with a view to lowering the resistance or controlling the work function thereof has been being studied.

In view of the means to form a metal electric wiring, the method called “the Damascene Process” has been established to a certain degree where Cu is used herein. Plainly, this method consists in combining the electroplating method and the chemical mechanical polishing (CMP) method. It has contributed to further contraction of the semiconductor device by having the concept of wet preparation into the method for fabricating the semiconductor device that has been heretofore based on a dry preparation. As a progressed version of this method, the method called “the Dual Damascene Process” has been already known. This method consists in executing a step of filling with a Cu material a via hole serving to establish electrical continuity to the metal electrical wiring in the lower layer part of the multilayer configuration simultaneously with the formation of the wiring and proves to be more efficient.

Particularly when Cu is used as a wiring material, however, a new problem arises. The problem is that Cu is easily oxidized and this oxidation not only remains on the surface but also advances rapidly to the interior. Even after the Cu wiring is formed, it never means that all the steps for fabricating the semiconductor device are completed. Subsequently, the Cu surface is more often than not exposed to the oxidizing atmosphere during the process of forming various thin films and fabricating a structure. In the first place, the Cu surface is eventually oxidized by the chemical that is used by the CMP method during the polishing step.

If this is a conventional Al wiring or Al alloy wiring, for example, and the surface thereof is consequently oxidized, the degree with which the cross section of the wiring conductor decreases is not so large because the oxide film of Al₂O₃ to be formed is comparatively strong and has a small thickness. In the case of the Cu wiring, since it does not form a strong passive film on the surface, the oxidation that starts from the surface in consequence of the exposure thereof to the ambient air or oxygen tends to advance deeply into the interior. In other words, the oxidation is at a disadvantage in greatly decreasing the cross section that can be utilized effectively as an electroconductive part and consequently increasing the wiring resistance in spite of the use of Cu. Of course, even when the electroconductive line is elongated as by forming a via hole configuration and causing other conductors to contact the surface part of the Cu wiring, the oxide film that happens to form on the surface results in increasing the contact resistance as a matter of course and, in the severe case, eventually rendering it impossible to secure the continuity.

As a means of cleaning treatment tentatively aimed at removing the oxide film inevitably formed on the surface of the Cu wiring, therefore, the method for removing the Cu surface oxide by a treatment using hydrogen gas or hydrogen plasma has been proposed as disclosed in Patent Documents 1 and 2 or the removal of the surface oxide has been implemented by adopting the sputtering treatment (argon milling) resorting to the impact of argon ion in combination with the method described above.

Patent Document 1: JP-A HEI 11-191556

Patent Document 2: JP-A HEI 11-186237

### DISCLOSURE OF THE INVENTION

### Problems the Invention Intends to Solve:

Claim 1 entered in each of Patent Documents 1 and 2, however, goes no further than using a description “the Cu surface is reduced,” as though intending to embrace the whole procedure of reduction. What is actually disclosed in the whole text of each publication is only the treatment of reduction in an atmosphere of hydrogen gas or in a hydrogen plasma as described above.

The reducing treatment using hydrogen of this nature is liable to inflict damage on peripheral structures, such as an interlayer insulating film, and particularly when the insulating film has a low permittivity, force this film to sustain this damage to the extent of raising the relative permittivity thereof Then, the elaborate use of a film of low permittivity has no meaning or brings only diminished effect. Further, the inevitable survival of hydrogen after the reducing treatment entails various problems. When the hydrogen plasma is used, it occurs more often than not that the hydrogen plasma itself inflicts damage directly on the device in the process of fabrication.

Besides, when the impact of argon ion is also exerted, not only the film of low permittivity sustains great damage but also the exposed wiring of the under layer is dug into the interior to deprive the under layer of flatness and the Cu removed by sputtering adheres again to the inner wall of the through hole to impair the result of embedding. At any rate, the observance of the future of the fabrication of semiconductor devices only advocates the wisdom of ousting the reducing treatment necessitating such intervention of hydrogen.

This invention has been perfected from the point of view suggested above and is aimed at providing a semiconductor device that has expelled the oxide film on the surface of a varying metal electroconductive layer material, such as Cu and an alloy thereof, most liable to entail a problem in the first place and Al, Co, Ni, Ti and Ta used as an electric wiring or a functional region without inflicting damage on peripheral structures, such as thin films of low permittivity, and a method and apparatus for the fabrication thereof

### Means for Solving the Problems

This invention, with a view to accomplishing the object mentioned above, is directed to providing a semiconductor device containing a metal electroconductive region and having at least part of an surface of the metal electroconductive region deprived of an oxide film by a reducing treatment by heating in an inert gas having an oxygen partial pressure suppressed to 1×10⁻¹³ atmosphere or less.

In the semiconductor device, the metal electroconductive region is formed of Cu or an alloy thereof containing at least one metal selected from the group consisting of Si, Al, Au, W, Mg, Be, Zn, Pd, Au, Cd, Hg, Pt, Zr, Ti, Sn, Ni and Fe.

In the semiconductor device, the surface of the metal electoconductive region deprived of the oxide film has a configuration having an insulating film or another metal electroconductive region kept in contact therewith.

This invention also provides a method for the fabrication of a semiconductor device containing a metal electroconductive region, comprising causing an oxide film formed on a surface of the metal electroconductive region to undergo a reducing treatment by heating the metal electroconductive region in an inert gas having at least an oxygen partial pressure suppressed to 1×10⁻¹³ atmosphere or less.

In the method, the metal electroconductive region is formed of Cu or an alloy thereof containing at least one metal selected from the group consisting of Si, Al, Au, W, Mg, Be, Zn, Pd, Cd, Au, Hg, Pt, Zr, Ti, Sn, Ni and Fe.

In the method, the heating is effected at a temperature of 450° C. or less when the metal electroconductive region is formed of Cu or an alloy thereof

In the method, the inert gas is selected from the group consisting of Ar, N, He, Ne, Xe and Kr.

The method for the fabrication of the semiconductor device further comprises, subsequent to the reducing treatment, depositing a passivation film on the surface of the metal electroconductive region under a vacuum or a low-oxygen atmosphere without being exposed to ambient air. Here, the passivation film is formed of a material selected from the group consisting of SiC, SiCN and SiN.

The method for the fabrication of the semiconductor device further comprises, subsequent to the reducing treatment, depositing another electroconductive region in contact with the surface of the metal electroconductive region under a vacuum or a low-oxygen atmosphere without being exposed to ambient air. Here, the another electroconductive region is formed of a material selected from the group consisting of TaN, Ta, Ti, TiN, Cu, Ni, Mo, Co, W and alloys thereof, or a material selected from alloys of Ni, Mo, Co and W having P or B incorporated therein.

An apparatus for the fabrication of a semiconductor device, comprises a reducing treatment chamber for storing a sample possessing a metal electroconductive region formed on a substrate and forming a closed space packed with an inert gas, an oxygen pump capable of lowering an oxygen partial pressure of the inert gas in the reducing treatment chamber to 1×10⁻¹³ atmosphere or less, and heating means for heating the metal electroconductive region in the reducing treatment chamber and removing an oxide film formed on a surface thereof by a reducing treatment.

In the apparatus, the reducing treatment chamber is a chamber used exclusively for the reducing treatment or a chamber used both as said reducing treatment chamber and as a film-forming chamber for forming another film.

As compared with the conventional reducing method using hydrogen or a hydrogen plasma as disclosed in Patent Documents 1 and 2 identified above, this invention that requires no aid of hydrogen brings about a far excellent effect. While the conventional method is at a disadvantage in inflicting damage on the insulating film that neighbors the metal electroconductive region subjected to reduction and suffering the thin film supposed to possess low permittivity to sustain damage and consequently entail an increase of the relative permittivity, this invention never entails such a problem at all. The problem derived from the survival of hydrogen can never take place even theoretically.

When the conventional method makes additional use of the removal of the oxide film as by argon milling, the metal electroconductive region is scraped off in the affected part and consequently suffered to form a difference in level. When another electroconductive region is formed contiguously in this part, it entails various mechanical and electrical problems and gives rise to defective embedding owing to the re-adhesion of the metallic material removed by sputtering as already mentioned. This invention has no possibility of entailing such a problem even theoretically and enables retention of an excellent surface flatness.

Since the oxygen partial pressure in the inert gas surrounding the metal electroconductive region is restrained to 1×10⁻¹³ atmosphere or less, by heating the region made of Cu, for example, to 400° C. at least or to 450° C. at most, it is rendered possible to remove the oxide film formed on the surface sufficiently by reduction without exerting any thermal damage on the peripheral structures such as an insulating film.

### BRIEF DESCRIPTION OF THE DRAWINGS

FIG. 1 is a schematic explanatory view of the principle of the present invention and the basic configuration of the apparatus for fabrication.

FIG. 2 is a schematic view showing the configuration of an oxygen pump used in the present invention.

FIG. 3 depicts spectra of copper and oxygen on the surface of a copper layer prior to undergoing a surface reducing treatment.

FIG. 4 depicts spectra of copper and oxygen on the surface of the copper layer subsequent to the reducing treatment according to the present invention.

FIG. 5 is an explanatory view showing an example of the process for the fabrication of a semiconductor device according to the present invention.

FIG. 6 is an explanatory view showing the example of the process for the fabrication of a semiconductor device according to the present invention, as continued from FIG. 5.

FIG. 7 is an explanatory view showing the example of the process for the fabrication of a semiconductor device according to the present invention, as continued from FIG. 6.

FIG. 8 is an explanatory view for comparing the process according to the present invention and the conventional process with respect to the via resistance in the copper region and the relative permittivity of the peripheral insulating film.

### EXPLANATION OF REFERENCE NUMERALS

10 Sample

11 Substrate

12 Metal electroconductive region

20 Apparatus for fabrication of semiconductor device

21-1, 21-2 Film-forming chamber

22 Reducing treatment chamber

24 Robot

30 Ocygen pump

31 Closed container

32 Solid electrolyte

51, 53, 59 Interlayer insulating film

57c, 68c Copper wiring

63p Copper plug

### BEST MODE FOR CARRYING OUT THE INVENTION

Now, the preferred embodiment of the present invention will be described in detail below. Prior to the description, the principle of this invention will be described.

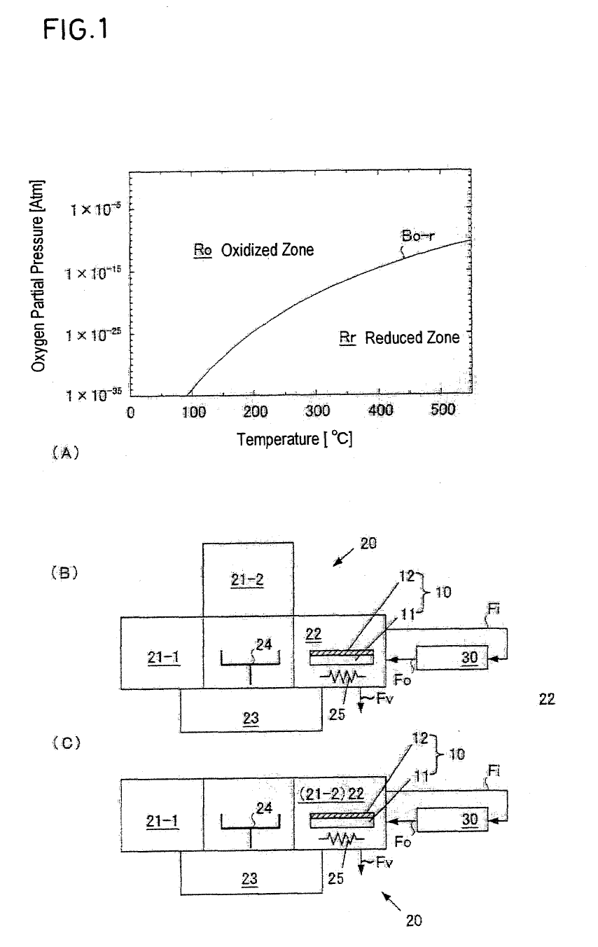

According to the law of thermodynamics, it is known that the oxidation reaction of a metal and the reverse reaction thereof (reducing reaction) are equilibrated under certain conditions of temperature and oxygen partial pressure. Consequently, when the metal electroconductive region (actually, a sample such as a structure on the semiconductor substrate containing the region) is heated under a certain oxygen partial pressure so as to increase the speed of reduction over the speed of oxygen, the heating by itself ought to enable the metal oxide to undergo a reducing treatment without requiring any aid of hydrogen. FIG. 1(A), for example, illustrates the equilibrium oxygen concentration of CuO. The CuO can be subjected to a reducing treatment by setting the reducing temperature and the oxygen partial pressure in the reduced zone Rr that falls below the equilibrium boundary curve Bo-r bordering on the oxidized zone Ro.

Heretofore, the proposal for implementing a reducing treatment in an oxygen partial pressure region that requires a reducing temperature to be 450° C. or less, preferably 400° C. or less, and does not require it to be heightened appreciably as is clear from FIG. 1(A), such as, for example, in an environment of oxygen partial pressure of less than 1×10⁻¹³ atmosphere or less has never been made at all. This is in the first place because a system capable of lowering the oxygen partial pressure to such a degree has never existed and therefore because the judgment that the reducing treatment aimed at cannot be accomplished until the reducing temperature is appreciably heightened has prevailed. In fact, this judgment has constituted one of ready-made ideas.

When the CuO already formed on the surface of a Cu electroconductive region is subjected to a reducing treatment, for example, since the recent semiconductor device aimed at enhancing the performance is more often than not provided peripherally with a film of low permittivity, at least the reducing temperature must be restrained to 450° C. or less. Otherwise, physical damages are exerted on the peripheral region, with the result that the enhancement of performance aimed at will no longer be accomplished. The ready-made idea mentioned above has ushered the conventional judgment that such an oxygen partial pressure environment as induces reduction in a relatively low temperature environment roughly falling short of 450° C. cannot be acquired. As a result, the reducing treatment in a hydrogen environment or due to the aid of hydrogen plasma has prevailed as disclosed in Patent Documents 1 and 2 identified above.

In this conventional technical situation, an electrochemical oxygen pump capable of lowering the oxygen partial pressure to the maximum of 1×10⁻³⁰ atmosphere has been developed, though for a different purpose, as disposed in JP-A 2002-326887 that includes as inventors thereof part of the present inventors. It has been advanced more recently to a device provided with a function of lowering the oxygen partial pressure to 1×10⁻³¹ atmosphere. It has grown into a structural device universally known to persons skilled in the art, though it is simply referred to as an oxygen pump.

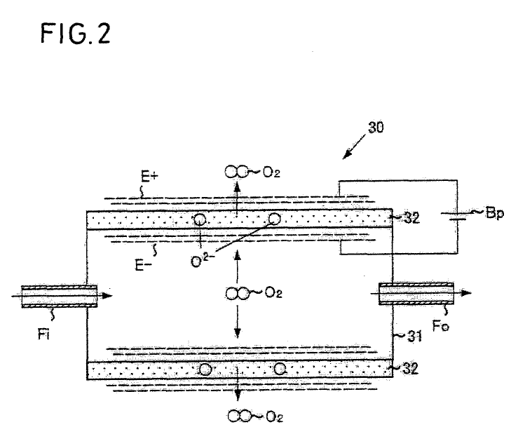

For the sake of precaution, the typical example of structure of this oxygen pump and the operating principle thereof will be described below by reference to FIG. 2. This oxygen pump 30 possesses a cylindrical closed container 31 having a hollow interior and opens at one end of the axial direction thereof the outlet of the inflow path Fi for an inert gas and at the other end the inlet of the outflow path Fo. Meantime, a solid electrolyte 32 possessing the ability to conduct oxide ions is disposed along the outer peripheral surface in the radial direction, and breathable electrodes of platinum, such as, for example, netlike electrodes E+ and E−, are disposed along the inner and outer peripheral surfaces of the solid electrolyte 32.

As the concrete examples of the solid electrolyte 32, the material examples 1 to 7 enumerated below may be cited. Among the material examples thus enumerated, the material example 1 is indeed most renowned.

### MATERIAL EXAMPLE 1

Zirconia-based materials represented by the general formula, (ZrO₂)_{1-x-y}(In₂O₃)ₓ(y₂O₃)_{y}(0<x<0.20, 0<y<0.20, 0.08<x+y<0.20).

### MATERIAL EXAMPLE 2

Materials, i.e. composite oxides containing Ba and In and having part of Ba substituted with La in the form of solid solution, particularly materials having an atomic number ratio {La/Ba+La)} of 0.3 or more or materials having part of In substituted with Ga.

### MATERIAL EXAMPLE 3

Materials represented by the general formula, {Ln₁₋ₓSrₓGa_{1-(y+z)}Mg_{y}CO_{z}O₃, wherein Ln denotes one or both of La and Nd, x=0.05 to 0.3, y=0 to 0.29, z=0.01 to 0.3 and y+z=0.025 to 0.3}.

### MATERIAL EXAMPLE 4

Materials represented by the general formula, {Ln₁₋ₓAₓGa_{(1-y-z)}B1_{y}B2_{z}O₃-d, wherein Ln denotes one or more members selected from the group consisting of La, Ce, Pr, Nd and Sm, A denotes one or more members selected from the group consisting of Sr, Ca and Ba, B1 denotes one or more members selected from the group consisting of Mg, Al and In, and B2 denotes one or more members selected from the group consisting of Co, Fe, Ni and Cu).

### MATERIAL EXAMPLE 5

Materials represented by the general formula, {Ln₂₋ₓMₓGe_{1-y}L_{y}O₅, wherein Ln denotes one or more members selected from the group consisting of La, Ce, Pr, Sm, Nd, Gd, Yd, Y and Sc, M denotes one or more members selected from the group consisting of Li, In, K, Rb, Ca, Sr and Ba, and L denotes one or more members selected from the group consisting of Mg, Al, Ga, In, Mn, Cr, Cu and Zn}.

### MATERIAL EXAMPLE 6

Materials represented by the general formula, {La₍₁₋ₓ₎SrₓGa_{(1-y-z)}Mg_{y}Al₂O₃, wherein 0<x≦0.2, 0<y≦0.2, and 0<z<0.4}.

### MATERIAL EXAMPLE 7

Materials represented by the general formula, {La₍₁₋ₓ₎AₓGa_{(1-y-z)}B1_{y}B2_{z}O₃, wherein Ln denotes one or more members selected from the group consisting of La, Ce, Pr, Sm and Nd, A denotes one or more members selected from the group consisting of Sr, Ca and Ba, B1 denotes one or more members selected from the group consisting of Mg, Al and In, B2 denotes one or more members selected from the group consisting of Co, Fe, Ni and Cu, x=0.05 to 0.3, y=0 to 0.29, z=0.01 to 0.3 and y+z=0.025 to 0.3}.

When an electric voltage is applied by a DC power source Bp to a pair of electrodes E+ and E− (the electrode E+ serving as a positive electrode) that nip the solid electrolyte 32 from inside and outside, however, the oxygen molecules (O₂) present in the closed container 31 are electrically reduced and ionized (O²⁻) by the solid electrolyte 32, passed inside the solid electrolyte 32 as drawn toward the positive electrode E+, and discharged again as oxygen molecules (O₂) to the exterior of the closed container 31. By causing the externally discharged oxygen molecules to be expelled while using an auxiliary gas like air as a carrier gas, it is rendered possible to remove the oxygen molecules in the inert gas supplied to the closed container 31 and effect control of the oxygen partial pressure thereof In fact, it has recently become possible to lower the oxygen partial pressure even to 1×10⁻³¹ atmosphere, with the improvement accomplished by the present inventors as a contributory factor.

Now, referring back to FIG. 1, this invention proposes a semiconductor device which possesses a function of removing oxide film and which is configured as described herein below and illustrated in FIGS. 1(B) and 1(C). First, a fabrication apparatus illustrated in FIG. 1(B) has a load lock chamber 23 possibly in a well-known already existing configuration and a mobile robot 24 disposed as mutually interlocked without rupturing vacuum. The robot 24 enables a sample 10 finally fabricated as a semiconductor device possessing the necessary function to be moved between a film-forming chamber and a reducing treatment chamber according to this invention preferably without rupturing vacuum.

In the illustrated case, plural (two as illustrated) film-forming chambers 21-1 and 21-2 are disposed in a connected relation similarly without rupturing vacuum. In the individual film-forming chambers 21-1 and 21-2, various thin films necessary for the purpose of assembling the semiconductor device as the final product are formed. Generally, the film-forming chambers 21-1 and 21-2, the load lock chamber 23 and a robot chamber are capable of being evacuated by an ordinary vacuum pump to the neighborhood of 1×10⁻⁸ atmosphere and are retained under a vacuum more often than not. In the present embodiment, a reducing treatment chamber 22 is disposed as connected to the film-forming chambers 21-1 and 21-2 without rupturing vacuum while being adapted to function as an independent room. It is provided with an exhaust system Fv and consequently enabled to evacuate the interior thereof Besides, it is connected to the electrochemical oxygen pump 30 as already described by reference to FIG. 2 and consequently enabled to lower the oxygen partial pressure of the inert gas (not shown) filling the interior thereof at least to 1×10⁻¹³ atmosphere and, when necessary, to about 1×10⁻³¹ atmosphere.

In the illustrated case, the inert gas in the reducing treatment chamber 22 flows through the inflow path Fi into the oxygen pump 30 and the inert gas subsequent to undergoing the treatment therein for lowering the oxygen partial pressure returns via the outflow path Fo again to the reducing treatment chamber 22. Alternatively, the inert gas source may be disposed at a special position and the inert gas of extremely low oxygen partial pressure produced from the oxygen pump 30 may be supplied to the reducing treatment chamber 22 and, after fulfilling the role thereof, exhausted from the exhaust system Fv.

For the sake of brevity, the sample 10 is illustrated in the drawing as consisting solely of a metal electroconductive region 12 of Cu, for example, formed on a substrate 11 that may be generally a silicon substrate. The metal electroconductive region 12 that has the surface thereof possibly oxidized is adapted to be heated with a well-known already existing heating means 25. In the drawing, the heating means 25 is solely indicated schematically with a heater mark similarly for the sake of explanation.

For the inert gas surrounding the sample 10, any gas can be used so long as it avoids inducing a chemical reaction with the component metals of the metal electroconductive region 12 at the operating temperature. It may be selected from the group consisting of Ar, N, He, Ne, Xe and Kr, for example.

Under the environment of the inert gas, the oxygen partial pressure of which is controlled to 1×10⁻¹³ atmosphere or less in the reducing reaction chamber 22 as described above, the metal electroconductive region 12 (substantially the whole of the sample 10) is heated to the maximum of 450° C., preferably to 400° C. or less, with a view to subjecting the surface oxide film to a reducing treatment. When the metal electroconductive region is formed of Cu or an alloy thereof, the surface oxide film can be sufficiently removed by the reduction even at a reducing temperature of 400° C. that is not relatively high at the oxygen partial pressure of 1×10⁻¹³ atmosphere of the inert gas. Even when the thin film of low permittivity has been formed in the periphery, the reducing treatment proceeds without inflicting thermal or mechanical damage thereto.

The pressure in the chamber during the reducing treatment may be either a reduced pressure or a normal pressure resulting from intercepting the vacuum pump. The spent gas may be exhausted from the device via the exhaust system Fv as already described or may be handled with a circulatory closed loop adapted to return the gas to the oxygen pump 30 via the inflow path Fi extended to the oxygen pump 30 and, when necessary, return the gas via the outflow path Fo to the reducing treatment chamber 22. When the circulation is elected, since the inert gas is purified more, the prescribed oxygen partial pressure can be reached in a shorter time.

The embodiment illustrated in FIG. 1(C) represents the case of causing one film-forming chamber 21-2 to serve concurrently as a reducing treatment chamber 22 instead of having the independent reducing treatment chamber 22 disposed in the aforementioned construction. Concerning the operation of reducing treatment and the process of reduction involved herein, the foregoing description can be called into use directly.

In this invention, by heating the sample 10 in the environment of the inert gas having an extremely low oxygen concentration, it is rendered possible to reduce the surface oxide of the metal electroconductive region 12 formed on the sample 10, form a clean metallic thin film and consequently shun inflicting damage on the peripheral structure. Without requiring any special aftertreatment or relying on subsequent exposure to the ambient air, therefore, the mobile robot 24 can be made to transport the sample 10 directly in the extremely high degree of vacuum or at least under the environment of low oxygen, deposit Cu or an alloy thereof as another electroconductive region directly on the surface of the metal electroconducive region in any of the film-forming chambers, or deposit directly a barrier metal of TaN, Ta, Ti, TiN or an alloy thereof or a cap metal of Ni, Mo, Co, W or an alloy thereof or of Ni, Mo, Co, W or an alloy thereof introducing P or B thereinto. For the sake of producing a chemically stable coating instead of the electroconductive region, the passivation insulating film, such as a thin film of SiC, SiCN or SiN, may be directly deposited. In other words, this invention, subsequent to sufficiently reducing and removing the surface oxide film, enables the naked surface to be directly coated with a different kind of film without suffering the surface to be oxidized again. The fact that the infliction of damage on the peripheral structure is avoided without using plasma or an active gas as has prevailed heretofore has an extremely large effect.

For the surface of the metal electroconductive region 12 that has been cleaned, the process for depositing another metal electroconductive region, such as, for example, an electroconductive region of Cu, Ta, N or Ta, as an intra-layer wiring or an interlayer wiring in the via configuration extending between the upper and lower layers of the multilayer construction may be implemented under a vacuum without being exposed to the ambient air or at least under the environment of low oxygen concentration.

Here, concrete examples of the reducing treatment will be cited for the purpose of demonstrating the effect of this invention. First, as the sample 10 indicated in FIG. 1(B) and FIG. 1(C), the product resulting from preparing a thin Cu film as a metal electroconductive region 12 in a thickness of 100 nm by sputtering on a silicon substrate 11 via a silicon nitride film of a thickness of 100 nm was used. This sample 10 was transported in advance into the independent reducing treatment chamber 22 while argon gas was introduced in 200 sccm via a mass flow controller into the oxygen pump 30 and the gas was introduced into the reducing treatment chamber 22 after the oxygen partial pressure thereof was lowered to 1×10⁻¹³ atmosphere. The degree of vacuum in the reducing treatment chamber itself was set at 1×10⁻³ atmosphere.

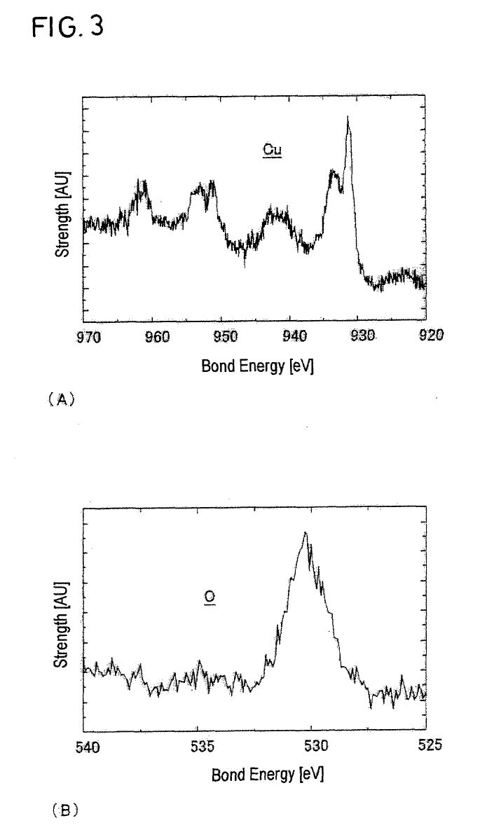

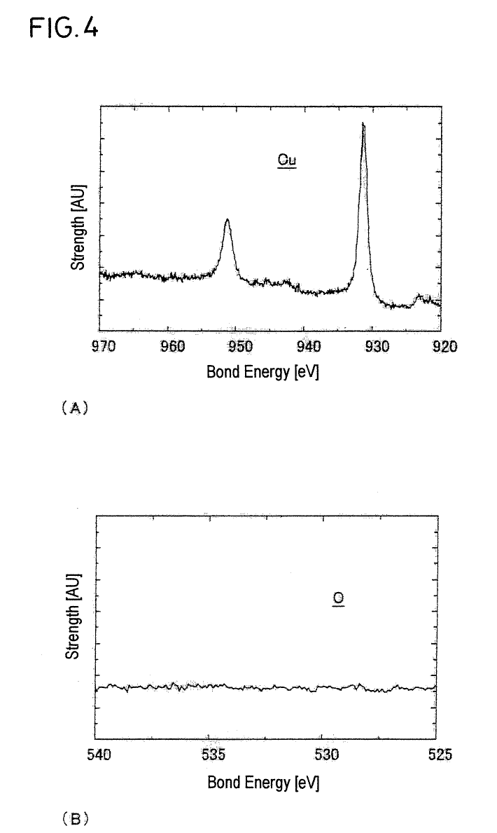

Under the ensuing conditions, the silicon substrate 11 was subjected to a heat treatment at 400° C. for one minute in an effort to reduce the copper oxide on the surface of the thin Cu film. For the purpose of examining the result of the heat treatment, the sample 10 was transported into a vacuum chamber equipped with an X-ray photoelectron spectrometer under a vacuum and made therein to produce a photoelectron spectrum. In contrast to the copper spectrum prior to the reducing treatment shown in FIG. 3(A) and the oxygen spectrum shown in FIG. 3(B), the copper spectrum subsequent to the reducing treatment shown in FIG. 4(A) and the oxygen spectrum shown in FIG. 4(B) were obtained. By comparing these spectra, it was clearly confirmed that the oxide on the thin Cu film visible prior to the reducing treatment was completely removed and the clean copper was exposed. When the sample was examined to determine the depth of reduction, it was confirmed that the reducing treatment advanced from the surface of the thin Cu film to the region of depth of 50 nm or more. This is an extremely favorable result of treatment that has never been attained heretofore.

Incidentally, the inert Ar gas that was used herein during the course of a reducing treatment was exhausted from the system by the vacuum pump. When the closed loop adapted to return the spent gas from the outlet of the vacuum pump again to the oxygen pump as described above was formed, it was confirmed that the reducing treatment could be similarly implemented. Further, even when the reducing treatment was carried out after the vacuum pump of the reducing treatment chamber was blocked prior to the reducing treatment and the treating chamber was filled with Ar gas of atmospheric pressure, the reducing treatment could be similarly carried out. Again in this case, equal effects were obtained when the spent gas was released as it was from the system and when the closed loop for returning the spent gas again to the oxygen pump was formed.

When the oxygen partial pressure was lowered to 1×10⁻³⁰ atmosphere and the sample was heated for one minute at a temperature of 140° C. or more by way of a separate experiment, the reducing treatment of the copper oxide on the surface could be accomplished in spite of this low temperature. The copper oxide partly survived, however, when the reducing temperature was lowered below 140° C. It was nevertheless an appropriate temperature in the light of the results of thermodynamic computation. Under the oxygen partial pressure of 1×10⁻³⁰ atmosphere, the reduction of CuO into Cu and O₂ requires the temperature to be 140° C. or more.

When the oxygen partial pressure was varied while the heating temperature was elevated to about 450° C., a level that might as well be regarded as the highest permissible temperature for the multilayer wiring process, in view of the heat resistance of the insulating film of low permittivity and the reliability of the copper wiring, the surface was reduced while the oxygen partial pressure was kept to 1×10⁻¹³ atmosphere or less and the copper oxide partially survived while the oxygen partial pressure exceeded this level. This is also a thermodynamically appropriate result.

An experiment directed to rendering the composition of the metal electroconductive region 12 variable was also carried out. In contrast to the foregoing experiment that used the metal electroconductive region having a composition of 100% Cu, the present experiment prepared copper alloys having Si, Al, Ag, W, Mg, B, Be, Zn, P, Pd, Cd, Au, Hg, Pt, Zr, Ti, Sn, Ni and Fe added respectively in a ratio of 1 to 10% to Cu and subjected these alloys to a reducing treatment under an oxygen partial pressure of 1×10⁻¹³ atmosphere at a reducing temperature of 450° C. In the alloy samples, the copper oxides on their surfaces invariably succumbed to a reducing treatment. Even when Ag having small specific resistance was used in the place of Cu, the silver oxides were enabled to undergo a reducing treatment by subjecting their surfaces to the reducing treatment under an equally low oxygen partial pressure.

Now, regarding the embodiment directed to forming a multilayer wiring by following such an effective procedure of this invention as described above, the process of fabrication will be described below.

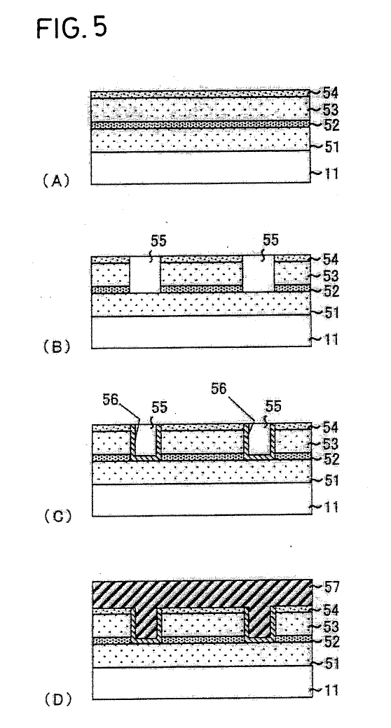

First, as illustrated in FIG. 5(A), an SiCN film 52 having a relative permittivity of 5 and intended as an etching stopper was deposited on a layered structure 51 having devices, such as transistors, and a device separating region (invariably omitted from illustration) formed in advance on a silicon substrate 11. Subsequently, an SiOC film having relative permittivity of 3 was deposited in a thickness of 400 nm as an interlayer insulating film 53. On this interlayer insulating film 53, an SiO₂ film 54 was deposited as a hard mask 54 to be used for processing.

Subsequently, grooves 55 intended to form an insulating film and a wiring by the known photolithography and dry etching technique were formed as illustrated in FIG. 5(B).

Thereafter, the resist pattern was removed by the O₂ ashing technique and the wet stripping technique and then a Cu layer 56 fated to serve as a film for preventing dispersion of Cu and also as a seed layer for the sake of Cu plating was continuously deposited so as to cover the inner wall of the wiring grooves 55 by applying the sputtering process under a high degree of vacuum as illustrated in FIG. 5(C).

Thereafter, a Cu layer 57 was formed by the plating process so as to fill in the wiring grooves 55 as illustrated in FIG. 5(D).

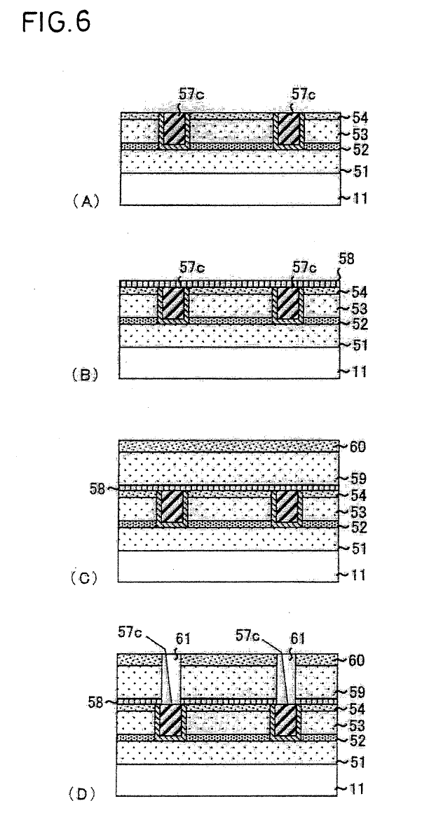

Then, the excess part of the Cu film excepting the interior of the wiring grooves 55 was removed by the CMP method described above to shape the wiring 57c tentatively as illustrated in FIG. 6(A).

When the sample consequently obtained was left standing in the ambient air, CuO and Cu₂O were formed on the outermost surface of the Cu wiring 57c. The oxidation of the outermost surface was confirmed by the photoelectron spectroscopy. When the reducing treatment was carried out for 3 minutes under the condition of having the sample jointly with the substrate 11 heated to 400° C. in the environment filled with Ar gas having an extremely low oxygen partial pressure of 1×10⁻³⁰ atmosphere in conformity with this invention, it was confirmed by the photoelectron spectroscopy that the copper oxide on the surface was reduced and the copper was exposed.

It was demonstrated that the reduction of Cu was accomplished so long as the oxygen partial pressure of the Ar gas was up to 1×10⁻¹³ atmosphere where the reducing temperature was 400° C. as described above. Conversely, when the oxygen partial pressure was retained at 1×10⁻³⁰ atmosphere, it was confirmed that the reduction of Cu was accomplished in spite of a further decrease of the temperature of the substrate so long as the temperature was at least 140° C. While the reducing treatment described here was performed under normal pressure, it may be carried out under a decreased pressure. Though the gas exhausted from the device was returned to the oxygen pump and put to circulation, it may be constantly exhausted and prevented from being returned to the oxygen pump.

After the Cu surface of the wiring 57c underwent the reducing treatment as described above in the case of the example of fabrication under discussion, the reducing treatment chamber 22 illustrated in FIGS. 1(B) and 1(C) was thoroughly evacuated, the robot 24 was made to transfer the substrate 11 under vacuum to the other film-forming chamber 21-1 or 21-2, an SiCN film 58 was deposited as a barrier insulating film (passivation film) 58 in a thickness of 50 nm by the chemical vapor phase growth method resorting to plasma excitation, and the sample was extracted to the ambient air. As the barrier insulating film 58, an SiC film or an SiN film may be used.

Incidentally, the aforementioned transportation of the substrate 11 may be implemented under an environment of low oxygen concentration instead of a vacuum. As the capping metal for covering the Cu surface resulting from the reducing treatment, it is permissible to select Ni, Mo, Co, W or alloys thereof, such as, for example, CoW or NiMo, or products resulting from having P or B incorporated in Ni, Mo, Co, W or alloys thereof, such as, for example, NiMoP or CoWP and deposit the capping metal by a proper depositing process.

The present inventor, in the final process described above, further tried a process for assembling a stacked structure instead of extracting the sample into the ambient air during the course of the final process. To describe one example of the process, the barrier insulating film 58 formed in the process illustrated in FIG. 6(B) was constructed as an etching stopper layer 58, an SiOC interlayer insulating film 59 having a relative permittivity of 3 was deposited thereon in a thickness of 200 nm as illustrated in FIG. 6(C), and a hard mask 60 of SiO₂ was further deposited thereon in a thickness of 100 nm.

Next, a through hole 61 measuring 200 nm in depth and 100 nm in diameter was bored in the interlayer insulating film 59 by the well-known already existing microfabrication technique, the surface of the etching stopper layer 58 was exposed through the bottom of the through hole 61, the etching stopper layer 58 was further removed by the etch back operation, and the upper surface of the underlying Cu wiring 57c was exposed through the bottom of the through hole 61 as illustrated in FIG. 6(D).

For the purpose of cleaning the consequently exposed surface of the Cu wiring 57c and reducing the possibly formed oxide film, the sample was subjected to the reducing treatment for 3 minutes by being heated at 400° C. under an extremely low oxygen partial pressure of 1×10⁻³⁰ atmosphere in accordance with the present invention. Ar gas was used as the inert gas and the reducing treatment was carried out under normal pressure. Then, the Ar gas exhausted from the reducing treatment device was returned again to the oxygen pump 30 illustrated in FIG. 1(B) and FIG. 1(C) and put to circulation.

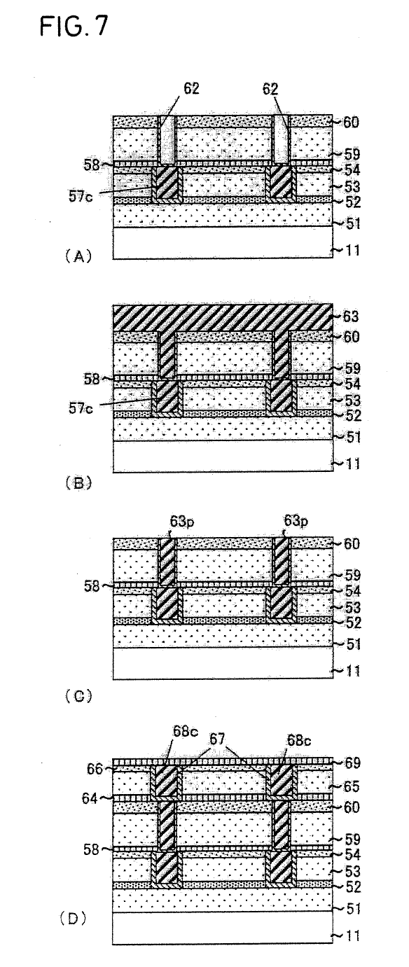

Subsequent to the reducing treatment, the reducing treatment chamber 22 illustrated in FIG. 1(B) and FIG. 1(C) was again evacuated, the robot 24 was made to transport the substrate 11 to the other film-forming chamber 21-1 or 21-2 under a vacuum or under an environment of low oxygen concentration as described above, then Ta or TaN, or Ti or TiN, or Cu was deposited by the sputtering process in a thickness of 20 nm on the inner peripheral surface of the through hole 61 and on the bottom thereof in the same procedure as already described in the process regarding FIG. 5(C), thereafter the through hole 61 had the interior thereof filled with a Cu layer 63 by the plating process as illustrated in FIG. 7(B), and the excess Cu layer 63 region was removed by the CMP method as illustrated in FIG. 7(C) to form a Cu plug 63p fated to serve as a longitudinal wiring.

In assembling such a configuration as this, while the conventional method shaved the surface of the Cu under layer 57c as by the argon milling and consequently suffered the Cu layer 63 in the through hole to bite into the Cu under layer 57c proportionately, this invention was able to form the Cu plug 63p of high quality level without having to shave the Cu under layer 57c at all. The flatness of the device could possibly constitute an important element particularly in fine structure.

Further, since this invention does not contemplate using the hydrogen plasma, it enabled retaining the hydrogen concentration in the joint between the upper and lower Cu layers and in the boundary face between the lower Cu layer 57c and the passivation film 58 below the minimum level of detection and markedly improving the adhesion in the boundary face of the two components. In the semiconductor device that has already completed fabrication, therefore, the conformity thereof with this invention can be judged by determining the residual hydrogen concentration in the periphery of the metal electroconductivity region that has become a clean surface because of the absence of any surviving oxide film.

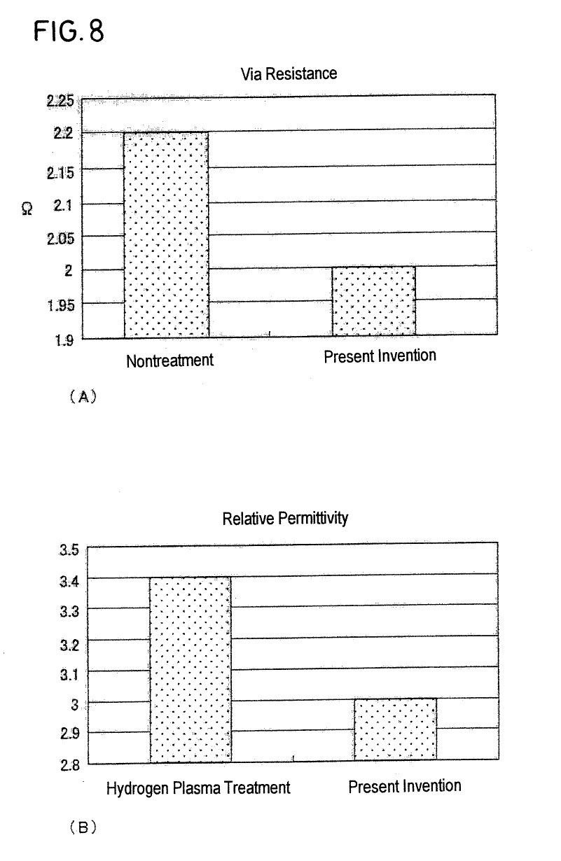

When the sample that had undergone the aforementioned series of treatments in accordance with this invention was tested for via resistance, the via resistance was found to have been lowered from the level, 2.2 Ω, existing prior to the treatment to roughly 2 Ω as shown in FIG. 8(A), indicating an effect of decreasing the resistance by about 10%. Further, this invention, as illustrated in FIG. 8(B), brings about no discernible increase in the relative permittivity of the SiCN interlayer insulating film from performing a reducing treatment. This effect of the invention is appreciably great in consideration of the fact that the same figure clearly shows that the relative permittivity in the conventional hydrogen plasma treatment is inferior by 0.4 to (higher than) this invention.

Naturally, as illustrated in FIG. 7(D), a multilayer structure may be obtained on the device structure illustrated in FIG. 7(C) by further forming an interlayer film 65 and a hard mask 66, opening a through hole 67 by the conventional process, forming a Cu wiring 68c therein and covering the surface thereof as with a passivation film 69. Further, by repeating this procedure, a semiconductor device provided with a stacked structure consisting of as many layers as necessary can be constructed.

While the foregoing embodiment has mainly covered the Cu wiring, it has been demonstrated that this invention is applicable to many kinds of metal used as wiring materials and, besides the wiring, to such kinds of metal used during the fabrication of transistors and that by heating Al to 1150° C. or more, Ti to 980° C. or more and Co and Ni to 400° C. or more under an oxygen partial pressure of 1×10⁻³⁰ atmosphere, the oxide on the surface can be similarly subjected to a reducing treatment.

In fact, in the transistor active element of the semiconductor device that results from the application of this invention, the fluctuation of the threshold voltage due to addition to charge could be suppressed by about 10% as compared with the conventional method, owing partly to the fact that this invention is capable of preventing the peripheral oxide film from dielectric breakdown.

As the oxygen pump in the sense of a functional device for controlling and lowering the oxygen partial pressure in the inert gas, the foregoing embodiment has contemplated using the oxygen pump 30 of the construction illustrated in FIG. 2. This invention naturally does not need to limit the oxygen pump thereto but may adopt the oxygen pump of any construction including the product to be developed in the future, so long as the oxygen pump is capable of lowering the oxygen partial pressure of the inert gas to be supplied to the reducing treatment chamber to at least 1×10⁻¹³ atmosphere.

Further, though the example of the process for fabrication described above by reference to FIGS. 5 to 7 has contemplated adopting the basic method in the so-called Damascene Process, i.e. the single Damascene Process so to speak, this invention is naturally capable of contemplating fabrication of a semiconductor device by the Dual Damascene Process described at the beginning of this description. In that case, this invention can be applied effectively.

1. A semiconductor device containing a metal electroconductive region and having at least part of an surface of the metal electroconductive region deprived of an oxide film by a reducing treatment by heating in an inert gas having an oxygen partial pressure suppressed to 1×10⁻¹³ atmosphere or less.

2. A semiconductor device according to claim 1, wherein said metal electroconductive region is formed of Cu or an alloy thereof containing at least one metal selected from the group consisting of Si, Al, Au, W, Mg, Be, Zn, Pd, Cd, Au, Hg, Pt, Zr, Ti, Sn, Ni and Fe.

3. A semiconductor device according to claim 1, wherein the surface of said metal electroconductive region deprived of the oxide film has a configuration having an insulating film or another metal electroconductive region held in contact therewith.

4. A method for the fabrication of a semiconductor device containing a metal electroconductive region, comprising causing an oxide film formed on a surface of said metal electroconductive region to undergo a reducing treatment by heating said metal electroconductive region in an inert gas having at least an oxygen partial pressure suppressed to 1×10⁻¹³ atmosphere or less.

5. A method for the fabrication of a semiconductor device according to claim 4, wherein said metal electroconductive region is formed of Cu or an alloy thereof containing at least one metal selected from the group consisting of Si, Al, Au, W, Mg, Be, Zn, Pd, Cd, Au, Hg, Pt, Zr, Ti, Sn, Ni and Fe.

6. A method for the fabrication of a semiconductor device according to claim 4, wherein the heating is effected at a temperature of 450° C. or less when said metal electroconductive region is formed of Cu or an alloy thereof.

7. A method for the fabrication of a semiconductor device according to claim 4, wherein said inert gas is selected from the group consisting of Ar, N, He, He, Xe and Kr.

8. A method for the fabrication of a semiconductor device according to claim 4, further comprising, subsequent to the reducing treatment, depositing a passivation film on the surface of said metal electroconductive region under a vacuum or a low-oxygen atmosphere without being exposed to ambient air.

9. A method for the fabrication of a semiconductor device according to claim 8, wherein said passivation film is formed of a material selected from the group consisting of SiC, SiCN and SiN.

10. A method for the fabrication of a semiconductor device according to claim 4, further comprising, subsequent to the reducing treatment, depositing another electroconductive region in contact with the surface of said metal electroconductive region under a vacuum or a low-oxygen atmosphere without being exposed to ambient air.

11. A method for the fabrication of a semiconductor device according to claim 10, wherein said another electroconductive region is formed of a material selected from the group consisting of TaN, Ta, Ti, TiN, Cu, Ni, Mo, Co, W and alloys thereof, or a material selected from alloys of Ni, Mo, Co and W having P or B incorporated therein.

12. An apparatus for the fabrication of a semiconductor device, comprising a reducing treatment chamber for storing a sample possessing a metal electroconductive region formed on a substrate and forming a closed space packed with an inert gas, an oxygen pump capable of lowering an oxygen spatial pressure of said inert gas in said reducing treatment chamber to 1×10⁻¹³ atmosphere or less, and heating means for heating said metal electroconductrive region in said reducing treatment chamber and removing an oxide film formed on a surface thereof by a reducing treatment.

13. An apparatus for the fabrication of a semiconductor device according to claim 12, wherein said reducing treatment chamber is a chamber used exclusively for the reducing treatment.

14. An apparatus for the fabrication of a semiconductor device according to claim 12, wherein said reducing treatment chamber is a chamber used both as said reducing treatment chamber and as a film-forming chamber for forming another film.
